(19) United States
(12) Patent Application Publication
(10) Pub. No.: US 2022/0302164 A1
(43) Pub. Date: Sep. 22, 2022

(54) SEMICONDUCTOR STORAGE DEVICE

(71) Applicant: KIOXIA CORPORATION, Tokyo (JP)

(72) Inventor: Mitsutaka INO, Mie Mie (JP)

(21) Appl. No.: 17/465,758

(22) Filed: Sep. 2, 2021

(30) Foreign Application Priority Data
Mar. 19, 2021 (JP) 2021-046668

(51) Int. Cl. H01L 27/11582; H01L 23/522; H01L 27/11519; H01L 27/11556; H01L 27/11565

(52) U.S. Cl. CPC H01L 27/11582; H01L 23/5226; H01L 27/11519; H01L 27/11556; H01L 27/11565

(57) ABSTRACT

According to one embodiment, a semiconductor storage device includes a semiconductor layer, a plurality of conductive layers stacked above the semiconductor layer, and a memory pillar. The memory pillar including a first insulating film extending through the plurality of conductive layers and having a planar elliptical, oval, or an oblong shape. The memory pillar having two channels inside the first insulating film insulated from one another and spaced from each other along a major axis. Each channel layer being thickest near a center portion along the major axis and thinning toward both end portions nearer the minor axis.

### CROSS-REFERENCE TO RELATED APPLICATION

This application is based upon and claims the benefit of priority from Japanese Patent Application No. 2021-046668, filed Mar. 19, 2021, the entire contents of which are incorporated herein by reference.

### FIELD

Embodiments described herein relate generally to a semiconductor storage device, a semiconductor memory device, a data storage device, or the like.

### BACKGROUND

A large-capacity non-volatile memory has been developed. The large-capacity non-volatile memory is capable of a low-voltage/low-current operation, a high-speed switching, and miniaturization/high integration of a memory cell.

In such a device, a large number of metal wirings referred to as bit lines and word lines must be arranged for the memory cell array of a large-capacity non-volatile memory. By applying a voltage to the bit lines and the word lines connected to a memory cell, data can be written to the memory cell. A semiconductor storage device has been proposed in which the memory cells are formed three-dimensionally from a stacked body of alternating conductive layers, which serves as the word lines, and insulating layers.

### BRIEF DESCRIPTION OF THE DRAWINGS

FIG. 1 is a block diagram of a semiconductor storage device according to a first embodiment.

FIG. 2 is a circuit diagram of one block BLK in a memory cell array according to a first embodiment.

FIG. 3 is a schematic view of a semiconductor storage device according to a first embodiment.

FIG. 4 is a schematic cross-sectional view of a semiconductor storage device according to a first embodiment.

FIG. 5 is another schematic cross-sectional view of a main part of the semiconductor storage device according to a first embodiment.

FIG. 6 is a schematic cross-sectional view of a memory pillar MP according to a first embodiment.

FIG. 7 is a schematic cross-sectional view of another example of a memory pillar MP according to a first embodiment.

FIG. 8 is a schematic view illustrating aspects related to a manufacturing process of a semiconductor storage device according to a first embodiment.

FIG. 9 is a schematic view illustrating aspects related to a manufacturing process of a semiconductor storage device according to a first embodiment.

FIG. 10 is a schematic view illustrating aspects related to a manufacturing process of a semiconductor storage device according to a first embodiment.

FIG. 11 is a schematic view illustrating aspects related to a manufacturing process of a semiconductor storage device according to a first embodiment.

FIG. 12 is a schematic view illustrating aspects related to a manufacturing process of a semiconductor storage device according to a first embodiment.

FIG. 13 is a schematic view of a semiconductor storage device according to a second embodiment.

FIG. 14 is a schematic view illustrating an arrangement of a memory pillar according to a second embodiment.

FIG. 15 is a schematic view of a semiconductor storage device according to a third embodiment.

### DETAILED DESCRIPTION

Embodiments provide a semiconductor storage device capable of high integration and increased storage density.

In general, according to one embodiment, a semiconductor storage device includes semiconductor layer and a plurality of conductive layers stacked above the semiconductor layer. Each conductive layer extends in a plane parallel to a first direction and a second direction intersecting the first direction and is spaced from an adjacent conductive layer in a third direction intersecting the first and second directions. A first memory pillar extends in the third direction through the plurality of conductive layers to the semiconductor layer. The first memory pillar includes a first insulating film on an outer peripheral surface of the first memory pillar and has an elliptical shape in a plane parallel to the first and second directions. A first channel layer is on an interior surface of the first insulating film and extends the length of the first memory pillar in the third direction. A second channel layer is on the interior surface of the first insulating film and also extends the length of the first memory pillar. An insulating core is between the first channel layer and the second channel layer in a direction parallel to a major axis of the elliptical shape of the first memory pillar. The insulating core electrically insulates the first channel layer from the second channel layer.

In this context, “an elliptical shape” refers to an ellipse, an oval, an irregular ellipse (non-symmetric foci), an egg shape, a rounded rectangular shape (e.g., a rectangle with rounded corners), or a racetrack shape (e.g., two semicircles or arcs joined by a straight portions).

Hereinafter, certain example embodiments will be described with reference to drawings. In the drawings, the same or substantially similar parts are designated by the same reference numerals.

In this specification, in order to illustrate a positional relationship of parts or the like, the upper direction of the drawings is referred to as an “upper”, “upward”, “higher”, or “above” direction or the like and the lower direction of the drawings is referred to as a “lower”, “below” direction or the like. In the specification, the concepts of “upper” and “lower” do not necessarily indicate the relationship with the direction of gravity.

### First Embodiment

A semiconductor storage device according to a first embodiment includes a semiconductor layer and a plurality of separate conductive layers provided above the semiconductor layer. The conductive layers extend in a first direction. A memory pillar in the semiconductor storage device includes a first insulating film therein and extends through the plurality of conductive layers. The memory pillar, or more particularly the first insulating film therein, may have an elliptical shape in a plane including the first direction and a second direction intersecting the first direction. Two first channels, each of which is provided inside the first insulating film, extend through the plurality of conductive layers face each other in a direction of the first major axis of the first insulating film, and have a shape in which a thickness near a center is the thickest within the plane and becomes thinner toward the end portions.

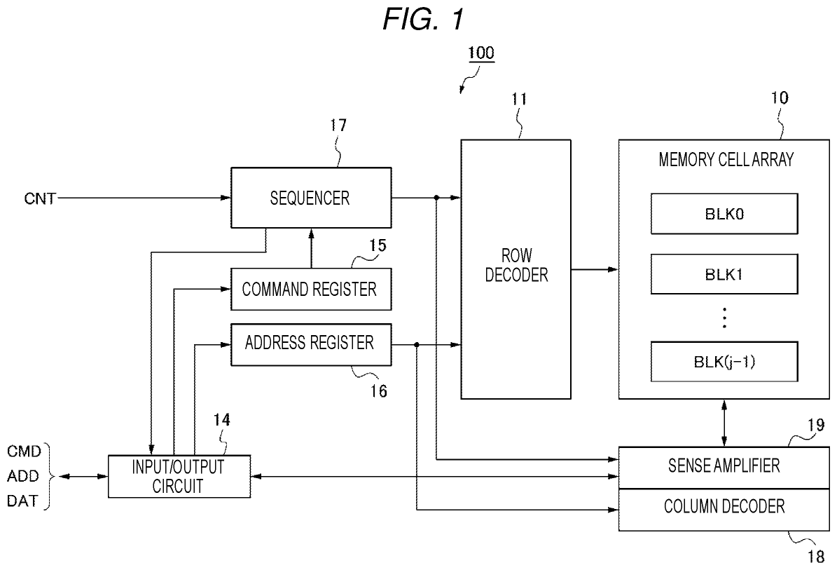

The semiconductor storage device 100 according to an embodiment is a NAND-type flash memory capable of storing data in a non-volatile manner. FIG. 1 is a block diagram of the semiconductor storage device 100 according to the first embodiment.

The semiconductor storage device 100 includes, for example, a memory cell array 10, a row decoder 11, a column decoder 18, a sense amplifier 19, an input/output circuit 14, a command register 15, an address register 16, and a sequencer (control circuit) 17.

The memory cell array 10 includes a total of j blocks BLK (BLK0 to BLK(j-1)), where j is an integer of 1 or more. Each of the blocks BLK includes a plurality of memory cell transistors. The memory cell transistor is electrically rewritable. The memory cell array 10 includes, for example, a plurality of bit lines, a plurality of word lines, and a source line, in order to control a voltage that is applied to the memory cell transistor.

The row decoder 11 receives a row address from the address register 16 and decodes the row address. The row decoder 11 performs a word line selection operation based on the decoded row address. Then, the row decoder 11 transfers the voltages necessary for a writing operation, a reading operation, or an erasing operation to the memory cell array 10.

The column decoder 18 receives a column address from the address register 16 and decodes the column address. The column decoder 18 performs a bit line selection operation based on the decoded row address.

The sense amplifier 19 detects and amplifies the data read from the memory cell transistor (s) to the bit line during a reading operation. Furthermore, the sense amplifier 19 transfers the data to be written (write data) to the bit line during a writing operation.

The input/output circuit 14 is connected to an external device (e.g., a host device) via a plurality of input/output lines (DQ lines). The input/output circuit 14 receives a command CMD and an address ADD from the external device. The command CMD received by the input/output circuit 14 is sent to the command register 15. The address ADD received by the input/output circuit is sent to the address register 16. Furthermore, the input/output circuit 14 performs the receiving/sending of data DAT from/to the external device.

The sequencer 17 receives a control signal CNT from the external device. The control signal CNT can be or include, for example, a chip enable signal CEn, a command latch enable signal CLE, an address latch enable signal ALE, a writing enable signal WEn, and a reading enable signal REn. When “n” is added as a suffix to a signal name this indicates an active low signal (an inverse (negated) logic signal of the base name signal). The sequencer 17 controls the operation of the entire semiconductor storage device 100 based on the commands CMD stored in the command register 15 and the control signal(s) CNT.

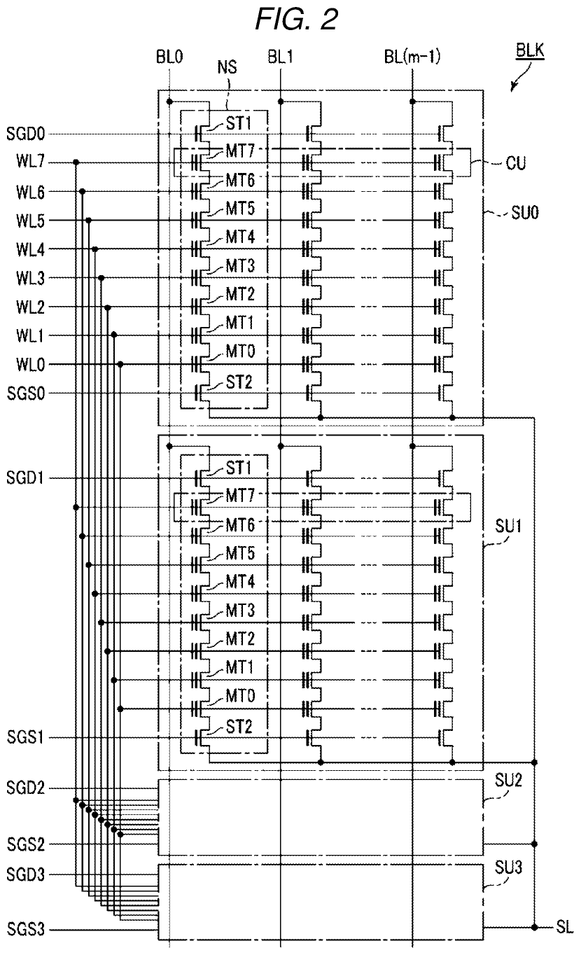

Subsequently, a circuit configuration of the memory cell array 10 will be described. FIG. 2 is a circuit diagram of one block BLK in the memory cell array 10.

Each of the plurality of blocks BLK includes a plurality of string units SU. In FIG. 2, four string units SU0 to SU3 are illustrated. The number of the string units SU in a block BLK may be any number.

Each of the string units SU includes a plurality of NAND strings (memory strings) NS. The number of the NAND strings NS in a string unit SU may be any number.

Each of the NAND strings NS includes a plurality of memory cell transistors MT and two selection transistors ST1 and ST2. The memory cell transistors MT are connected in series between a source of the selection transistor ST1 and a drain of the selection transistor ST2. In this specification, the memory cell transistor may be called “memory cell” or “cell”. A configuration example in which the NAND string NS includes eight memory cell transistors MT (MT0 to MT7) is illustrated in FIG. 2 for simplification. The number of the memory cell transistors MT in the NAND string NS is greater than this in actual, and further, may be any number. The memory cell transistor MT includes a control gate electrode and a charge storage layer, and stores data in a non-volatile manner. The memory cell transistor MT may store 1 bit data or 2 or more bit data.

Gates of the selection transistors ST1 in the string unit SU0 are connected to the selection gate line SGD0. In the same manner, gates of the plurality of selection transistors ST1 in the string units SU1 to SU3 are connected to selection gate lines SGD1 to SGD3, respectively. Gates of the plurality of selection transistors ST2 in the string unit SU0 are connected to the selection gate line SGS0. In the same manner, gates of the plurality of selection transistors ST2 in the string units SU1 to SU3 are connected to selection gate lines SGS1 to SGS3, respectively. The string units SU0 to SU3 in each block BLK may be connected to a common selection gate line SGS. Control gates of the memory cell transistors MT0 to MT7 in each block BLK are connected to word lines WL0 to WL7, respectively.

The drains of the selection transistors ST1 of the NAND strings NS in the same row (among the NAND strings NS arranged in a matrix manner in each block BLK) are connected to one of the bit lines BL0 to BL(m-1), where “m” is an integer of 1 or more. Each bit line BL is connected to a plurality of blocks BLK, and is connected to one NAND string NS in each string unit SU in each of the blocks BLK. The sources of the plurality of selection transistors ST2 in each block BLK are connected to a source line SL in common. The source line SL is connected to, for example, a plurality of blocks BLK.

The data in the plurality of memory cell transistors MT in a block BLK is, for example, collectively erased. Reading and writing are performed on the plurality of memory cell transistors MT in one string unit SU and connected to the same word line WL. A set of memory cell transistors MT that shares the same word line WL in a string unit SU is referred to as a “cell unit CU”. A collection of 1 bit data stored in each of the plurality of memory cell transistors MT in the cell unit CU is referred to as a “page”. That is, the writing operation and the reading operation for the cell unit CU are performed in a page unit.

The NAND string NS may include a dummy cell transistor. For example, two dummy cell transistors can be connected in series between the selection transistor ST2 and the memory cell transistor MT0. For example, two dummy cell transistors can be connected in series between the memory cell transistor MT7 and the selection transistor ST1. Gates of a plurality of dummy cell transistors are connected to a plurality of dummy word lines, respectively. The structure of the dummy cell transistor is the same as that of the memory cell transistor. However, the dummy cell transistor is not provided to store valid data, but to alleviate the disturbances (e.g., write disturb) that might otherwise be received by a memory cell transistor or the selection transistor during the writing operation or the erasing operation.

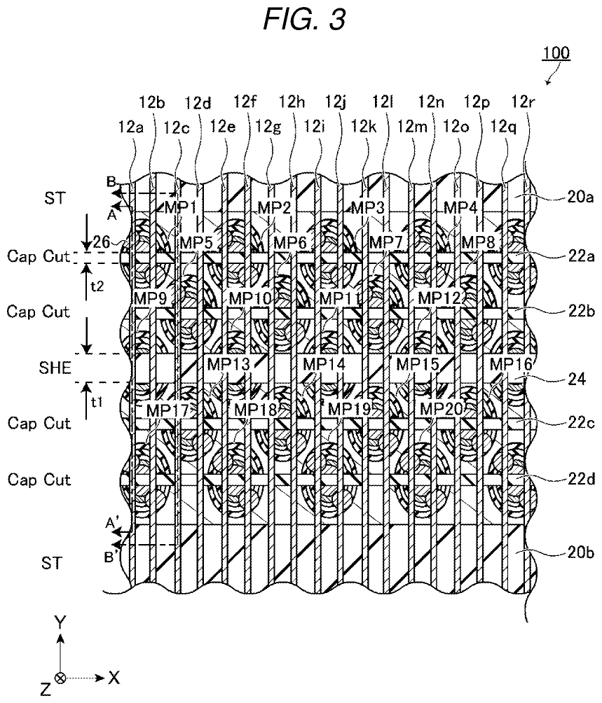

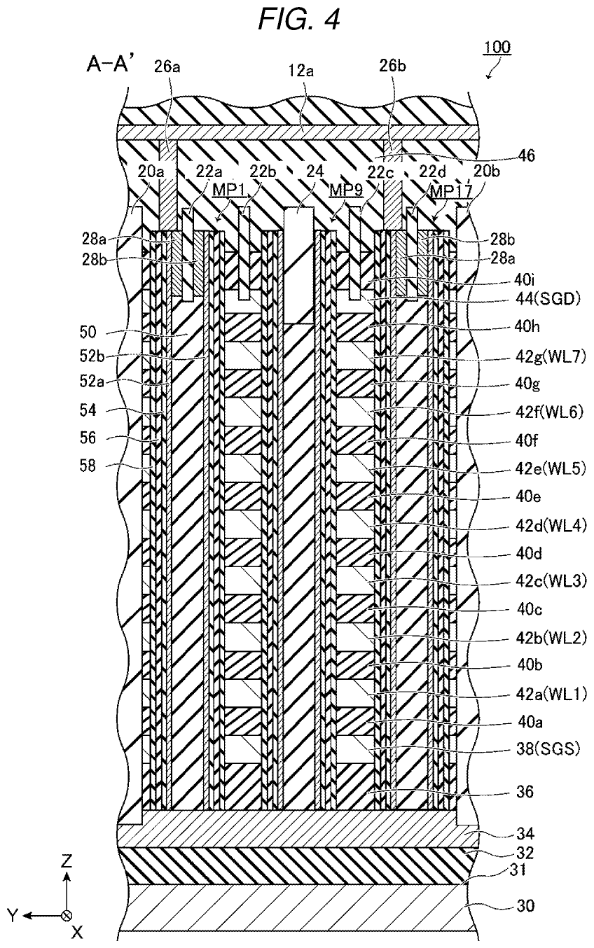

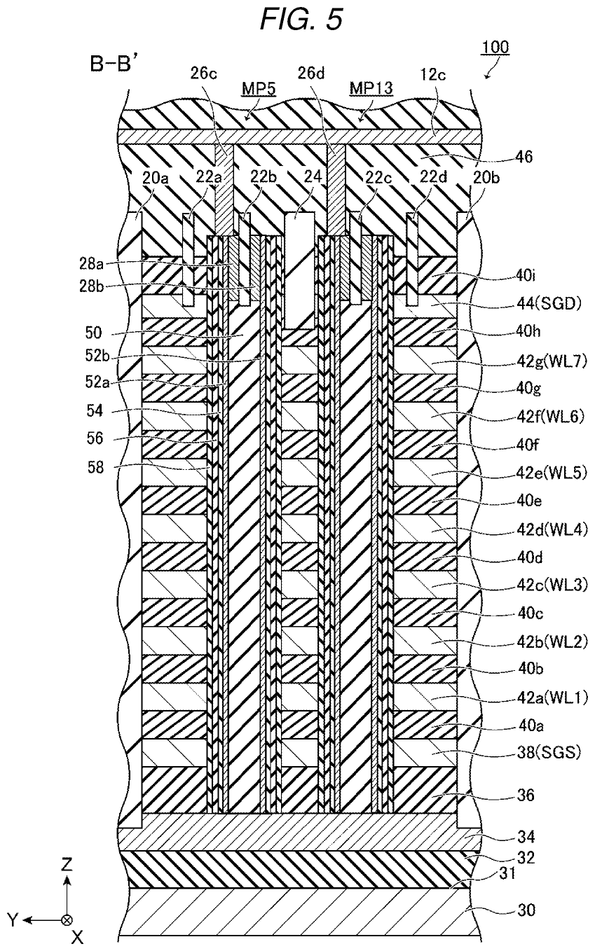

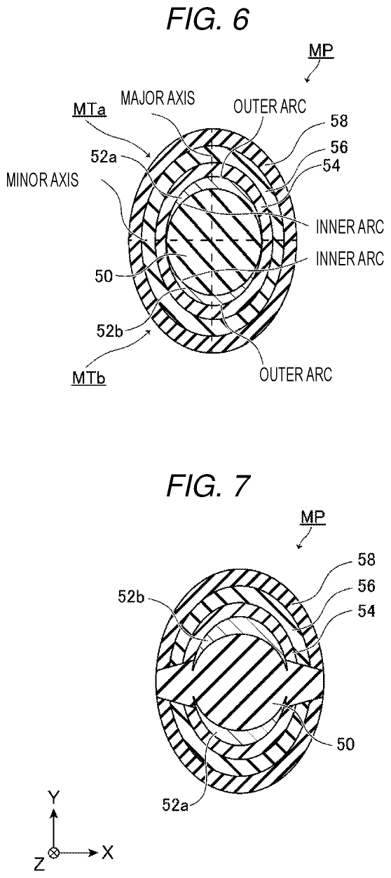

FIG. 3 is a schematic cross-sectional view of a semiconductor storage device 100 according to the first embodiment. FIG. 4 is a schematic cross-sectional view of a semiconductor storage device 100 according to the first embodiment. FIG. 4 is a schematic cross-sectional view that would be obtained by cutting the semiconductor storage device 100 along line A-A′ in FIG. 3. FIG. 5 is a schematic cross-sectional view of the semiconductor storage device according to the first embodiment. FIG. 5 is a schematic cross-sectional view that would be obtained by cutting the semiconductor storage device 100 along line B-B′ in FIG. 3. FIG. 6 is a schematic cross-sectional view of a memory pillar MP according to the first embodiment. In FIG. 3, the illustration of an insulating layer 46 is omitted.

The semiconductor storage device 100 will be described with reference to FIGS. 3 to 6.

FIG. 3 is a schematic cross-sectional view in which the bit lines 12 are exposed.

The semiconductor layer 30 (see FIG. 4) comprises, for example, a semiconductor material. The semiconductor layer 30 comprises, for example, monocrystalline silicon. The semiconductor layer 30 includes a semiconductor layer surface 31. In FIGS. 4 and 5, the semiconductor layer 30 is disposed such that the XY plane and the semiconductor layer surface 31 are in parallel with each other. For the semiconductor layer 30, for example, a semiconductor wafer or an SOI wafer or portions thereof may be used.

An insulating layer 32 is provided on the semiconductor layer 30. The insulating layer 32 comprises, for example, silicon and oxygen, such as silicon oxide or the like.

A conductive layer 34 is provided on the insulating layer 32. The conductive layer 34 comprises, for example, polycrystalline silicon containing impurities. The conductive layer 34 functions as the source line SL. The conductive layer 34 in some examples may comprise a stacked film in which a conductive layer comprising polycrystalline silicon, for example, a conductive layer comprising a metal material such as tungsten (W), and a conductive layer comprising polycrystalline silicon are stacked.

An insulating layer 36 is provided on the conductive layer 34. The insulating layer 36 comprises, for example, silicon and oxygen.

A single-layered conductive layer 38 that functions as the selection gate line SGS is provided on the insulating layer 36. A plurality of conductive layers 42 that function as the word lines WL is provided above the conductive layer 38. In FIGS. 4 and 5, a conductive layer 42a, a conductive layer 42b, a conductive layer 42c, a conductive layer 42d, a conductive layer 42e, a conductive layer 42f, and a conductive layer 42g are illustrated and are referred to in the description collective as conductive layers 42.

A single-layered conductive layer 44 that functions as the selection gate line SGD is provided above the conductive layer 42. The insulating layer 40 comprising, for example, silicon and oxygen is provided between the conductive layer 38 and the conductive layer 42a, between the different conductive layers 42, and between the conductive layer 42g and the conductive layer 44.

The conductive layer 38 and the plurality of conductive layers 42 each comprise, for example, tungsten (W). The conductive layer 38 and the plurality of conductive layers 42 may include a barrier metal film comprising, for example, titanium nitride (TiN) on the upper surface, side surface, and bottom surface of the portion comprised of tungsten (W). The conductive layer 38 and the plurality of conductive layers 42 extend in parallel with the conductive layer surface 31.

In FIGS. 4 and 5, one conductive layer 38 that functions as the selection gate line SGS and the conductive layer 44 that functions as the selection gate line SGD are illustrated. However, a plurality of conductive layers 38 (that function as selection gate lines SGS) and a plurality of conductive layers 44 (that function as the selection gate lines SGD) may be provided. The conductive layer 38, the conductive layers 42, and the conductive layer 44 may be divided into different portions in a plane in parallel with the XY plane (or the semiconductor layer surface 31).

A plurality of memory pillars MP penetrates the insulating layer 36, the conductive layer 38, the plurality of insulating layers 40, the plurality of conductive layers 42, and the conductive layer 44. Lower end portions of the memory pillars MP are connected to the conductive layer 34. Upper end portions of the plurality of memory pillars MP extend through the insulating layer 40i and protrude into the insulating layer 46 provided above the insulating layer 40i. The insulating layer 46 comprises, for example, silicon and oxygen.

As illustrated in FIG. 3 and FIG. 6, the shape of each of the memory pillars MP in the plane in parallel with the XY plane is a substantially elliptical shape having a major axis parallel with the Y axis and a minor axis parallel with the X axis.

A memory pillar MP1, a memory pillar MP2, a memory pillar MP3, and a memory pillar MP4 are arranged in the X direction in a row. A memory pillar MP5, a memory pillar MP6, a memory pillar MP7, and a memory pillar MP8 are arranged in the X direction in a row. A memory pillar MP9, a memory pillar MP10, a memory pillar MP11, and a memory pillar MP12 are arranged in the X direction in a row. A memory pillar MP13, a memory pillar MP14, a memory pillar MP15, and a memory pillar MP16 are arranged in the X direction in a row. A memory pillar MP17, a memory pillar MP18, a memory pillar MP19, and a memory pillar MP20 are arranged in the X direction in a row.

An insulating film 20a and an insulating film 20b (referred to collectively as an insulating film 20) divide the insulating layer 36, the conductive layer 38, the plurality of insulating layers 40, the plurality of conductive layers 42, and the conductive layer 44, for example, in the Z direction. The memory pillar MP1, the memory pillar MP2, the memory pillar MP3, the memory pillar MP4, the memory pillar MP5, the memory pillar MP6, the memory pillar MP7, the memory pillar MP8, the memory pillar MP9, the memory pillar MP10, the memory pillar MP11, the memory pillar MP12, the memory pillar MP13, the memory pillar MP14, the memory pillar MP15, the memory pillar MP16, the memory pillar MP17, the memory pillar MP18, the memory pillar MP19, and the memory pillar MP20 are provided between the insulating film 20a and the insulating film 20b in the plane in parallel with the XY plane. The insulating film 20 comprises, for example, silicon and oxygen.

The memory pillar MP17, the memory pillar MP9, and the memory pillar MP1 are arranged in the Y direction in a column. The memory pillar MP13 and the memory pillar MP5 are arranged in the Y direction in a column. The memory pillar MP18, the memory pillar MP10, and the memory pillar MP2 are arranged in the Y direction in a column. The memory pillar MP14 and the memory pillar MP6 are arranged in the Y direction in a column. The memory pillar MP19, the memory pillar MP11, and the memory pillar MP3 are arranged in the Y direction in a column. The memory pillar MP15 and the memory pillar MP7 are arranged in the Y direction in a column. The memory pillar MP20, the memory pillar MP12, and the memory pillar MP4 are arranged in the Y direction in a column. The memory pillar MP16 and the memory pillar MP8 are arranged in the Y direction in a column.

Thus, when viewed in the Y direction, the memory pillar MP5 is at an X direction position between the memory pillar MP1 and the memory pillar MP2, the memory pillar MP6 is similarly between the memory pillar MP2 and the memory pillar MP3, and the memory pillar MP7 is similarly between the memory pillar MP3 and the memory pillar MP4.

When viewed in the Y direction, the memory pillar MP10, the memory pillar MP11, and the memory pillar MP12 are respectively disposed between the memory pillar MP5 and the memory pillar MP6, the memory pillar MP6 and the memory pillar MP7, and the memory pillar MP7 and the memory pillar MP8.

When viewed in the Y direction, the memory pillar MP13, the memory pillar MP14, and the memory pillar MP15 are respectively disposed between the memory pillar MP9 and the memory pillar MP10, the memory pillar MP10 and the memory pillar MP11, and the memory pillar MP11 and the memory pillar MP12.

When viewed in the Y direction, the memory pillar MP18, the memory pillar MP19, and the memory pillar MP20 are respectively disposed between the memory pillar MP13 and the memory pillar MP14, the memory pillar MP14 and the memory pillar MP15, and the memory pillar MP15 and the memory pillar MP16.

The memory pillars MP each includes a block insulating film 58, a charge storage film 56, a tunnel insulating film 54, a channel 52, and a core member 50. The block insulating film 58, the charge storage film 56, the tunnel insulating film 54, the channel 52, and the core member 50 penetrate the insulating layer 36, the conductive layer 38, the insulating layers 40, the conductive layers 42, and the conductive layer 44. The insulating layer 36, the conductive layer 38, the insulating layer 40, the conductive layer 42, or the conductive layer 44 is disposed around the memory pillar MP. In the cross-section in FIG. 6, one conductive layer 42 is disposed around the memory pillar MP, but the illustration of the conductive layer 42 is omitted.

The block insulating film 58 is provided in the memory pillar MP, and has a substantially elliptical outer shape in the plane in parallel with the XY plane. The block insulating film 58 has a tube shape. The block insulating film 58 is a film that prevents the flow of charges between the conductive layer 38, the conductive layer 42, or the conductive layer 44 and the charge storage film 56. The block insulating film 58 comprises, for example, silicon and oxygen, or silicon, oxygen, and nitrogen.

The charge storage film 56 is provided inside the block insulating film 58, and has a substantially elliptical outer shape in a plane in parallel with the XY plane. The charge storage film 56 has a tube shape. The charge storage film 56 is a film capable of storing charges. The charge storage film 56 comprises, for example, silicon and nitrogen, or silicon, oxygen, and nitrogen.

The tunnel insulating film 54 is provided inside the charge storage film 56, and has a substantially elliptical outer shape in the plane in parallel with the XY plane. The tunnel insulating film 54 has a tube shape. The tunnel insulating film 54 is an insulating film that is insulating but permits a current flow when a predetermined voltage is applied across the film. The tunnel insulating film 54 comprises, for example, silicon and oxygen, or silicon, oxygen, and nitrogen.

The channel 52 is provided inside the tunnel insulating film 54. In FIG. 6, a channel 52a and a channel 52b are illustrated. Each of the channel 52a and the channel 52b has a crescent moon shape (shape like crescent or oxbow lake) in the plane in parallel with the XY plane. In this context, the crescent moon shape refers to a shape in which the thickness near the center of the channel 52a and the channel 52b is the thickest, then the thickness becomes thinner toward both end portions. The crescent moon shape is curved (bowed) in one direction. The channel 52a and the channel 52b are disposed such the center portion (where the thickness is the thickest) is oriented in the direction of the major axis. The channel 52a and the channel 52b are disposed such that inner arcs of the crescent moon shape are facing each other. The inner arcs of the channel 52a and the channel 52b are separated from each other in the direction of the major axis. The outer arc of the channel 52a and the outer arc of the channel 52b are both in contact with, for example, the inner wall surface of the tunnel insulating film 54.

Each channel 52 (52a, 52b) is a pillar comprising, for example, a semiconductor material such as polycrystalline silicon. Each channel 52 (52a, 52b) is electrically connected to the conductive layer 34.

The core member 50 is provided inside the tunnel insulating film 54 to be between the inner arc of the channel 52a and the inner arc of the channel 52b. The core member 50 comprises, for example, oxygen and silicon.

In other words, each channel 52 (52a, 52b) is provided between the core member 50 and the tunnel insulating film 54. The tunnel insulating film 54 is provided surrounding both the core member 50 and the channels 52 (52a, 52b). The charge storage film 56 is provided surrounding the tunnel insulating film 54. The block insulating film 58 is provided surrounding the charge storage film 56.

A memory cell transistor MTa includes the channel 52a, a part of the tunnel insulating film 54, apart of the charge storage film 56, a part of the block insulating film 56, a part of the associated conductive layer 42.

A memory cell transistor MTb includes the channel 52b, a part of the tunnel insulating film 54, apart of the charge storage film 56, a part of the block insulating film 58, a part of the associated conductive layer 42.

For example, one memory pillar MP includes two NAND strings, one of which includes the memory cell transistor MTa and the other of which includes the memory cell transistor MTb.

In the following description the block insulating film 58, the charge storage film 56, and the tunnel insulating film 54 are collectively referred to as a “first insulating film.” These insulating films (58, 56, 54) can each have a substantially elliptical outer shape in the plane in parallel with the XY plane (or the semiconductor layer surface 31). That is, the first insulating film (comprised of these insulating films 58, 56, 54) can be said to have a substantially elliptical outer shape.

A fifth insulating film 22 (“Cap Cut” 22) is provided above the conductive layer 42g to be between the channel 52a and the channel 52b in the memory pillars MP. A lower portion of the fifth insulating film 22 impinges into the core member 50 and thus a portion of the fifth insulating film 22 is provided inside the core member 50. For example, as illustrated in FIG. 3, the fifth insulating film 22 extends lengthwise in the X direction. In FIG. 3, a fifth insulating film 22a, a fifth insulating film 22b, a fifth insulating film 22c, and a fifth insulating film 22d are illustrated.

The fifth insulating film 22a divides the upper portion of the memory pillar MP1, the upper portion of the memory pillar MP2, the upper portion of the memory pillar MP3, and the upper portion of the memory pillar MP4. The fifth insulating film 22b divides the upper portion of the memory pillar MP5, the upper portion of the memory pillar MP6, the upper portion of the memory pillar MP7, and the upper portion of the memory pillar MP8. The fifth insulating film 22c divides the upper portion of the memory pillar MP13, the upper portion of the memory pillar MP14, the upper portion of the memory pillar MP15, and the upper portion of the memory pillar MP16. The fifth insulating film 22d divides the upper portion of the memory pillar MP17, the upper portion of the memory pillar MP18, the upper portion of the memory pillar MP19, and the upper portion of the memory pillar MP20. The fifth insulating films 22 comprise, for example, silicon and oxygen.

A conductive portion 28 is provided in separate portions (28a, 28b) inside the channels 52 (52a, 52b) of each memory pillar MP above the conductive layer 42g. The conductive portion 28a is between the channel 52a and the fifth insulating film 22. The conductive portion 28b is between the channel 52b and the fifth insulating film 22. Here, descriptions will be made using conductive portion 28a and conductive portion 28b in the memory pillar MP1 illustrated in FIG. 4 as an example. The conductive portion 28a is provided between the tunnel insulating film 54 (or the channel 52a) and the fifth insulating film 22a, and is electrically connected to the channel 52a. The conductive portion 28b is provided between the tunnel insulating film 54 (or the channel 52b) and the fifth insulating film 22a, and is electrically connected to the channel 52b. In other words, the fifth insulating film 22a is provided at an above portion of the memory pillar MP1 between the channel 52a and the channel 52b. The conductive portion 28a and the conductive portion 28b are insulated (electrically separated) from each other by the fifth insulating film 22a. The conductive portion 28a is an example of a first conductive portion, and the conductive portion 28b is an example of a second conductive portion.

The conductive portions 28 are also referred to, for example, as cap silicon. The conductive portions 28 comprise, for example, polycrystalline silicon doped with impurities (dopants). The material of the conductive portion 28 is not limited to doped polycrystalline silicon. A conductive portion 28 provides a good electrical connection between a contact pillar 26 (see FIG. 3) and a channel 52.

The conductive portion 28a is electrically connected to the NAND string including the memory cell transistor MTa by being electrically connected to the channel 52a. The conductive portion 28b is electrically connected to the NAND string including the memory cell transistor MTb by being electrically connected to the channel 52b.

A fourth insulating film 24 is provided above the conductive layer 42g and divides the conductive layer 44 (used as the selection gate line SGD). The fourth insulating film also extends through and divides the upper portion of the memory pillar MP9, the upper portion of the memory pillar MP10, the upper portion of the memory pillar MP11, and the upper portion of the memory pillar MP12. When a plurality of conductive layers 44 is provided, the fourth insulating film 24 may divide the plurality of conductive layers 44. The fourth insulating film 24 divides at least the conductive layer 44 disposed at the top of the stack of conductive layers (the plurality of conductive layers 42 and the conductive layer 44). The fourth insulating film 24 divides at least the conductive layer 44 used as a selection gate line SGD. The fourth insulating film 24 comprises, for example, silicon and oxygen.

The contact pillars 26 are provided on the memory pillars MP and are electrically connected to a channel 52 or a conductive portion 28. Here, when describing the case of the memory pillar MP1 as an example, as illustrated in FIG. 4, a contact pillar 26a is provided on the memory pillar MP1, and is electrically connected to the channel 52a and the conductive portion 28a. A contact pillar 26 electrically connected to the channel 52b of the memory pillar MP1 and the conductive portion 28b is also provided on the memory pillar MP1 but is not depicted in the cross-sectional view of FIG. 4 (but see FIG. 3). In other words, since FIG. 4 illustrates the cross-section taken along line A-A′, the contact pillar 26 electrically connected to the channel 52b and the conductive portion 28b is provided at a position that is not illustrated in FIG. 4. The contact pillars 26 comprise, for example, tungsten (W).

In the same manner, the contact pillars 26 are provided on the memory pillar MP5, the memory pillar MP6, the memory pillar MP7, the memory pillar MP8, the memory pillar MP13, the memory pillar MP14, the memory pillar MP15, the memory pillar MP16, the memory pillar MP17, the memory pillar MP18, the memory pillar MP19, and the memory pillar MP20. It is not necessary to provide contact pillars 26 on the memory pillar MP9, the memory pillar MP10, the memory pillar MP11, and the memory pillar MP12.

Each bit line 12 is provided on a contact pillar 26. Each bit line 12 extends in the Y direction parallel with the XY plane. In FIG. 3, a bit line 12a, a bit line 12b, a bit line 12c, a bit line 12d, a bit line 12e, a bit line 12f, a bit line 12g, a bit line 12h, a bit line 12i, a bit line 12j, a bit line 12k, a bit line 12l, a bit line 12m, a bit line 12n, a bit line 12o, a bit line 12p, a bit line 12q, and a bit line 12r are illustrated and these are collectively referred to as bit lines 12 and any one may be referred to as a bit line 12. Each bit line 12 is, for example, copper (Cu) or tungsten (W).

The connection between the bit lines 12 and the memory pillar MP1 and the memory pillar MP17 will be described with reference to FIG. 4. The channel 52a of the memory pillar MP1 and the conductive portion 28a of the memory pillar MP1 are connected to the bit line 12a via the contact pillar 26a. The channel 52b of the memory pillar MP1 and the conductive portion 28b of the memory pillar MP1 are electrically connected to the bit line 12b (see FIG. 3) via another contact pillar 26.

The channel 52a of the memory pillar MP17 and the conductive portion 28a of the memory pillar MP17 are electrically connected to the bit line 12a via a contact pillar 26b. The channel 52b of the memory pillar MP17 and the conductive portion 28b of the memory pillar MP17 are electrically connected to the bit line 12b (see FIG. 3) via another contact pillar 26.

The connection between the bit lines 12 and the memory pillar MP5 and the memory pillar MP13 will be described with reference to FIG. 5. The channel 52a of the memory pillar MP5 and the conductive portion 28a of the memory pillar MP5 are connected to the bit line 12c via a contact pillar 26c. The channel 52b of the memory pillar MP5 and the conductive portion 28b of the memory pillar MP5 are connected to the bit line 12d via another contact pillar 26 (see FIG. 3).

The channel 52a of the memory pillar MP13 and the conductive portion 28a of the memory pillar MP13 are electrically connected to the bit line 12c via a contact pillar 26d. The channel 52b of the memory pillar MP13 and the conductive portion 28b of the memory pillar MP13 are electrically connected to the bit line 12d via another contact pillar 26 (see FIG. 3).

In the semiconductor storage device according to the embodiment, in order to perform the reading operation or the like on the memory cell transistor MTa and the memory cell transistor MTb on the same memory pillar MP, the same conductive layer 42 is used as the word line WL for both. In order to selectively perform the reading operation or the like on the memory cell transistor MTa and the memory cell transistor MTb on the same memory pillar MP, a different bit line 12 is used for each.

As illustrated in FIG. 3, a width t1 of the fourth insulating film 24 in the Y direction is greater than a width t2 of the fifth insulating film 22 in the Y direction.

FIG. 7 is a schematic cross-sectional view of another example of a memory pillar MP according to the first embodiment. In this other example, the core member 50 divides the tunnel insulating film 54, the charge storage film 56, and the block insulating film 58 in the X direction.

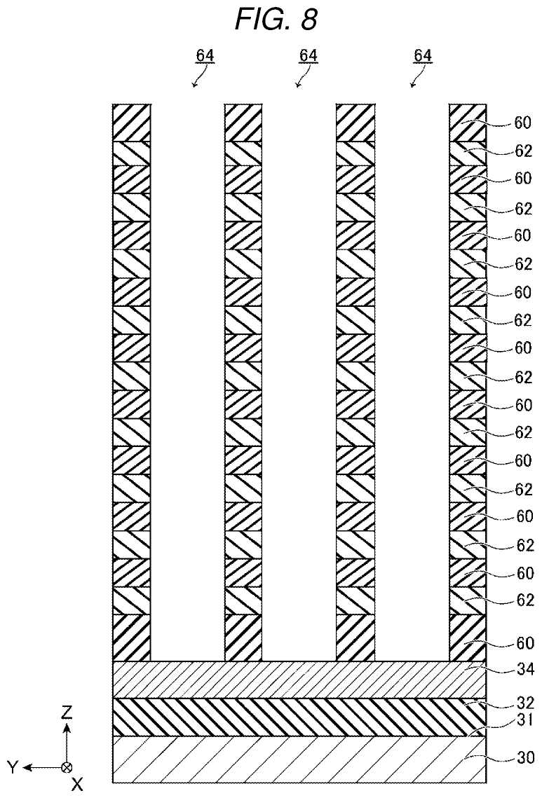

A method for manufacturing the semiconductor storage device according to an embodiment will be described with reference to FIGS. 8 to 11.

First, the insulating layer 32 comprising, for example, oxygen and silicon is formed on the semiconductor layer 30. Subsequently, the conductive layer 34 comprising, for example, polycrystalline silicon containing impurities is formed on the insulating layer 32. Subsequently, a plurality of insulating layers 60 (comprising, for example, silicon and oxygen) and a plurality of sacrificial layers 62 (comprising, for example, silicon and nitrogen) are alternately stacked on the conductive layer 34 by one by one by a chemical vapor deposition (CVD) method, for example. The openings 64 (see also FIG. 8) have a substantially planar elliptical shape with a major axis in parallel with the Y axis and a minor axis in parallel with the X axis. The openings 64, which extend in the Z direction, are formed using a photoresist as a mask in a photolithographic and reactive ion etching (RIE) process.

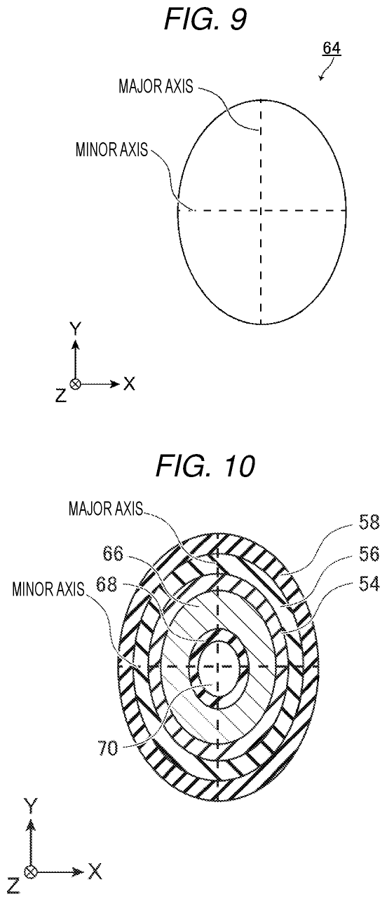

FIG. 9 illustrates a schematic view of an opening 64 when viewed in the Z direction. The illustration of the plurality of insulating layers 60 that surround the outside of each opening 64 is omitted from FIG. 9. The manufacturing method will be described by focusing on the processing associated with the opening 64 and the formation of various aspects inside of the opening 64 for the formation of a memory pillar MP.

FIG. 10 depicts block insulating film 58 (comprising, for example, silicon and oxygen or silicon, oxygen, and nitrogen) is formed in the opening 64 by, for example, a CVD method. Next, the charge storage film 56 (comprising, for example, silicon and nitrogen or silicon, oxygen, and nitrogen) is formed on the interior surface of the block insulating film 58 by, for example, a CVD method. Subsequently, the tunnel insulating film 54 (comprising, for example, silicon and oxygen or silicon, oxygen, and nitrogen) is formed on the interior surface of the charge storage film 56. Next, a film comprising amorphous silicon is formed on the interior surface of the tunnel insulating film 54 by, for example, a CVD method. Subsequently, a polycrystalline silicon film 66 is formed by crystallizing the previously deposited amorphous silicon film by using a heat treatment. An oxide film 68 (comprising oxygen and silicon) is also formed on the interior surface of the polycrystalline silicon film 66 by such heat treatment. A hole 70 that has an elliptical shape with a major axis parallel to the Y axis and a minor axis parallel to the X axis is remains unfilled inside the oxide film 68 at this time.

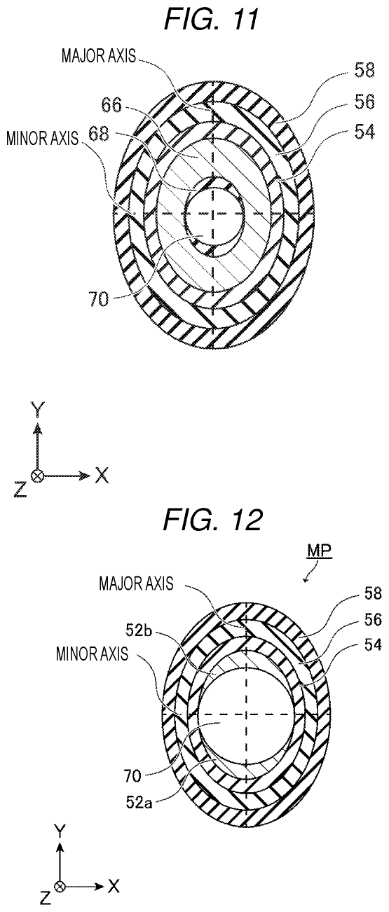

A part of the oxide film 68 is then removed by wet etching using, for example, dilute hydrofluoric acid (DHF). In this process, the portions of oxide film 68 formed on the major axis side are more difficult to remove (etch slower) by the wet etching than the portions of oxide film 68 formed on the minor axis side. Therefore, the polycrystalline silicon film 66 on the minor axis side is more readily exposed to the hole 70 and the portion of oxide film 68 on the major axis side is not entirely removed (see FIG. 11). A reason why the oxide film 68 on the major axis side is more difficult to remove than the oxide film 68 formed on the minor axis side is that for the oxide film 68 formed in the opening 64 having a substantially elliptical shape, a larger stress is applied in the major axis direction than the minor axis direction.

A part of the polycrystalline silicon film 66 and the oxide film 68 are removed by wet etching using, for example, a mixed solution of trimethyl-2-hydroxyethylammonium hydroxide and hydrogen peroxide. The wet etching is performed such that the polycrystalline silicon film 66 on the major axis side, is not entirely removed. Furthermore, the wet etching is performed such that the polycrystalline silicon film 66 on the minor axis side is removed and the tunnel insulating film 54 is exposed to the hole 70. Therefore, portions of the polycrystalline silicon film 66 remaining on the major axis ends become the channel 52a and the channel 52b (see FIG. 12). The channel 52a and the channel 52b are separated from each other (that is, they are not connected to one another). In other words, only a part of the polycrystalline silicon film 66 is removed by wet etching since the oxide film 68 is used as a partial mask.

When forming the memory pillar MP illustrated in FIG. 7, the tunnel insulating film 54, the charge storage film 56, and the block insulating film 58 are entirely removed from a region along the minor axis direction using the polycrystalline silicon film 66 as a mask.

The memory pillar MP illustrated in FIG. 6 (or FIG. 7) is completed by filling the hole 70 with the core member 50 material (comprising, for example, silicon and oxygen).

Subsequently, the sacrificial layers 62 are removed and replaced with the conductive layer 38, the conductive layer 42, and the conductive layer 44. For example, the sacrificial layers 62 are removed by wet etching using phosphoric acid (H₃PO₄) via the opening 64 (in which the insulating film 20a and the insulating film 20b are formed later).

Next, the conductive layer 38, the conductive layers 42, and the conductive layer 44 comprising tungsten (W) and the barrier metal film can be formed by, for example, a CVD method.

After forming the conductive layer 38, the conductive layers 42, and the conductive layer 44, the insulating film 20 is formed inside the opening 64 used for such wet etching. As a result of the replacement process, the sacrificial layers 62 are substituted by the conductive layer 38, the conductive layers 42, and the conductive layer 44, the lowermost insulating layer 60 becomes the insulating layer 36, and the other insulating layers 60 become the corresponding insulating layers 40.

The insulating layer 46 (comprising, for example, silicon and oxygen), the contact pillar 26 (comprising, for example, tungsten (W)), and the bit lines 12 (comprising, for example, copper (Cu) or tungsten (W)) are formed on the uppermost insulating layer 40, and thus, the semiconductor storage device 100 according to the first embodiment is obtained.

The method for the manufacturing the semiconductor storage device according to the present disclosure is not limited to the above, and for example, other processes such as a heat treatment may be performed.

Operations and effects of the first embodiment will be described.

In the semiconductor storage device according to the first embodiment, the memory pillar MP extends through a plurality of conductive layers (38, 42, 44) and includes a first insulating film that has a substantially elliptical shape in a plane in parallel with the semiconductor layer surface. Furthermore, the memory pillar MP has two channels (52a, 52b) that each extend in the memory pillar MP through the plurality of conductive layers. The channels (52a, 52b) are separated from each other in the direction of the major axis of the first insulating film. The channel layers (52a, 52b) also each have a crescent moon shape in the plane in parallel with the semiconductor layer surface.

Therefore, it is possible to perform a reading operation or the like on each of the NAND strings in on the same memory pillar MP. As a result, it is possible to provide a semiconductor storage device with high integration.

A semiconductor storage device according to at least one embodiment further includes a fifth insulating film 22 provided to separate the channels. A fifth insulating film 22 is provided between a first conductive portion 28a and a second conductive portion 28b.

Therefore, it is possible to provide a good electrical connection between the contact pillars 26 and the channels 52. Furthermore, the electrical connection from the two bit lines above a memory pillar MP to the NAND strings (memory strings) belonging to the same memory pillar MP is more easily provided. In particular, in a plane in parallel with the XY plane, when the same conductive layer 42 is used as the word line for the reading operation or the like on each of the NAND strings (memory strings) belonging to the same memory pillar MP, the electrical connection from the two bit lines 12 above the memory pillar MP to each of the NAND strings may be configured as described above.

### Second Embodiment

A semiconductor storage device according to the second embodiment is different from the semiconductor storage device according to the first embodiment in that the semiconductor storage device of the second embodiment has a plurality of first memory pillars that are elliptical shaped and spaced from each other in a row along a first direction, the first memory pillars are provided such that a direction of the first minor axis of the elliptical shape is rotated clockwise by a first predetermined angle from the first direction. The second embodiment further includes a plurality of second memory pillars that are elliptical shaped and spaced from each other in a row along a first direction. The row of first memory pillars is spaced from the row of second memory pillars in a second direction. Each of the second memory pillars has a second minor axis of the elliptical shape rotated counterclockwise by a second predetermined angle from the first direction such that the second major axis direction of the second memory pillars crosses the first major axis direction of the first memory pillars. The description of the aspects overlapping with the first embodiment is omitted.

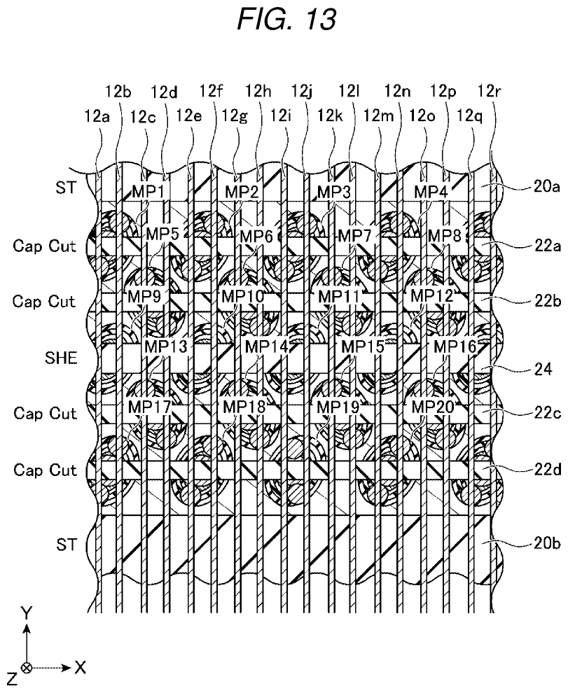

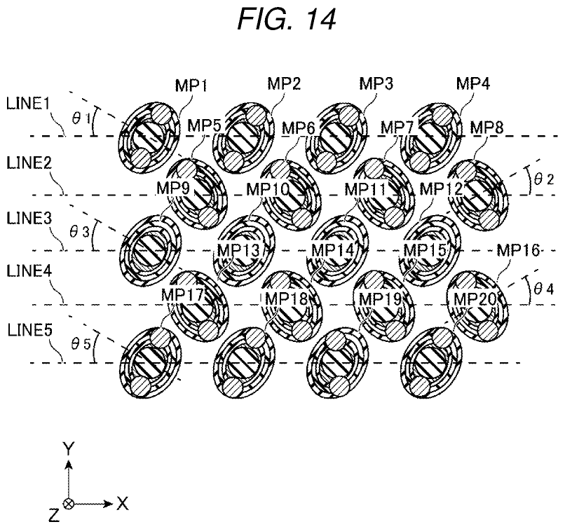

FIG. 13 is a schematic cross-sectional view of a semiconductor storage device according to the second embodiment. FIG. 14 is a schematic cross-sectional view illustrating the memory pillar MP in FIG. 13 in order to illustrate the arrangement of the memory pillars MP according to the second embodiment.

In FIG. 14, each of LINE1, LINE2, LINE3, and LINE4 is a line in parallel with the X direction. The memory pillar MP1, the memory pillar MP2, the memory pillar MP3, and the memory pillar MP4 are provided such that, when viewed in the Z direction, each minor axis thereof is rotated clockwise by a first predetermined angle θ1 from the X direction in the plane in parallel with the XY plane or the semiconductor layer surface 31. The memory pillar MP1, the memory pillar MP2, the memory pillar MP3, and the memory pillar MP4 are be arranged in the X direction.

The memory pillar MP5, the memory pillar MP6, the memory pillar MP7, and the memory pillar MP8 are provided such that, when viewed in the Z direction, each minor axis thereof is rotated counterclockwise by a second predetermined angle θ2 from the X direction in the plane in parallel with the XY plane or the semiconductor layer surface 31. The memory pillar MP5, the memory pillar MP6, the memory pillar MP7, and the memory pillar MP8 are arranged in the X direction. When viewed in the Y direction, the memory pillar MP5 is disposed at a position (along the X direction) between the memory pillar MP1 and the memory pillar MP2. When viewed in the Y direction, the memory pillar MP6 is disposed at a position between the memory pillar MP2 and the memory pillar MP3. When viewed in the Y direction, the memory pillar MP7 is disposed at a position between the memory pillar MP3 and the memory pillar MP4.

The memory pillar MP5, the memory pillar MP6, the memory pillar MP7, and the memory pillar MP8 include the block insulating film 58, the charge storage film 56, the tunnel insulating film 54, the channel 52, and the core member 50. The block insulating film 58, the charge storage film 56, the tunnel insulating film 54, the channel 52, and the core member 50 penetrate the insulating layer 36, the conductive layer 38, the insulating layers 40, the conductive layers 42, and the conductive layer 44.

The block insulating film 58, the charge storage film 56, and the tunnel insulating film 54 (referred to collectively as a second insulating film) are provided in the memory pillar MP. These insulating films (58, 56, 54) each have a substantially elliptical outer shape in the plane in parallel with the XY plane (or the semiconductor layer surface 31). The direction of the minor axis of this elliptical outer shape is rotated counterclockwise by the second predetermined angle θ2 from the X direction when viewed in the Z direction.

The memory pillar MP9, the memory pillar MP10, the memory pillar MP11, and the memory pillar MP12 are provided such that, when viewed in the Z direction, each minor axis thereof is rotated clockwise by a third predetermined angle θ3 from the X direction in the plane in parallel with the XY plane or the semiconductor layer surface 31. The memory pillar MP9, the memory pillar MP10, the memory pillar MP11, and the memory pillar MP12 are arranged in the X direction. When viewed in the Y direction, the memory pillar MP10 is disposed at a position between the memory pillar MP5 and the memory pillar MP6. When viewed in the Y direction, the memory pillar MP11 is disposed at a position between the memory pillar MP6 and the memory pillar MP7. When viewed in the Y direction, the memory pillar MP12 is disposed at a position between the memory pillar MP7 and the memory pillar MP8.

The memory pillar MP13, the memory pillar MP14, the memory pillar MP15, and the memory pillar MP16 are provided such that, when viewed in the Z direction, each minor axis thereof is rotated counterclockwise by a fourth predetermined angle θ4 from the X direction in the plane in parallel with the XY plane or the semiconductor layer surface 31. The memory pillar MP13, the memory pillar MP14, the memory pillar MP15, and the memory pillar MP16 are arranged in the X direction. When viewed in the Y direction, the memory pillar MP13 is disposed at a position between the memory pillar MP9 and the memory pillar MP10. When viewed in the Y direction, the memory pillar MP14 is disposed at a position between the memory pillar MP10 and the memory pillar MP11. When viewed in the Y direction, the memory pillar MP15 is disposed at a position between the memory pillar MP11 and the memory pillar MP12.

The memory pillar MP17, the memory pillar MP18, the memory pillar MP19, and the memory pillar MP20 are provided such that, when viewed in the Z direction, each minor axis thereof is rotated clockwise by a fifth predetermined angle θ5 from the X direction in the plane in parallel with the XY plane or the semiconductor layer surface 31. The memory pillar MP17, the memory pillar MP18, the memory pillar MP19, and the memory pillar MP20 are arranged in the X direction. When viewed in the Y direction, the memory pillar MP18 is disposed at a position between the memory pillar MP13 and the memory pillar MP14. When viewed in the Y direction, the memory pillar MP19 is disposed at a position between the memory pillar MP14 and the memory pillar MP15. When viewed in the Y direction, the memory pillar MP20 is disposed at a position between the memory pillar MP15 and the memory pillar MP16.

In at least one embodiment, the first predetermined angle, the second predetermined angle, the third predetermined angle, the fourth predetermined angle, and the fifth predetermined angle are equal to each other. However, the first predetermined angle, the second predetermined angle, the third predetermined angle, the fourth predetermined angle, and the fifth predetermined angle do not have to be equal to each other.

According to the semiconductor storage device according to the second embodiment, an additional degree of freedom in the rotation direction in the arrangement of the memory pillars MP is obtained. As a result, it is possible to take an arrangement in which the intervals between the bit lines 12 in the X direction are narrowed. For example, an arrangement in which the distance between the memory pillar MP1 and the memory pillar MP5 increases in the plane in parallel with the XY plane or the semiconductor layer surface 31 can be provided, and thus, it is possible to provide an arrangement in which phosphoric acid H₃PO₄ or a tungsten (W) precursor more easily enters during replacement processing steps.

### Third Embodiment

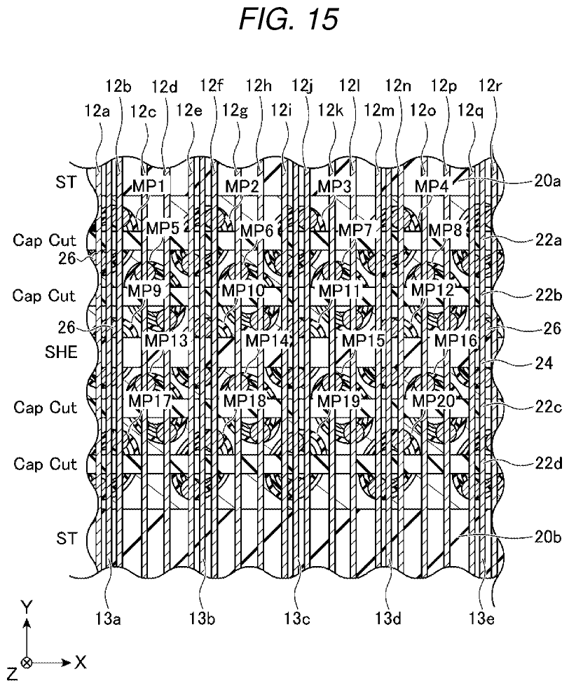

FIG. 15 is a schematic cross-sectional view of a semiconductor storage device according to the third embodiment. In the third embodiment, a contact pillar 26 is also provided on each of the memory pillar MP9, the memory pillar MP10, the memory pillar MP11, and the memory pillar MP12.

The contact pillar 26 provided on the memory pillar MP9 is electrically connected to a bit line 13a (an example of a third wiring) that is provided between the bit line 12a (an example of a first wiring) and the bit line 12b (an example of a second wiring).

The contact pillar 26 provided on the memory pillar MP10 is electrically connected to a bit line 13b that is provided between the bit line 12e and the bit line 12f.

The contact pillar 26 provided on the memory pillar MP11 is electrically connected to a bit line 13c that is provided between the bit line 12i and the bit line 12j.

The contact pillar 26 provided on the memory pillar MP12 is electrically connected to the bit line 13a that is provided between the bit line 12a and the bit line 12b.

The memory pillar MP9, the memory pillar MP10, the memory pillar MP11, and the memory pillar MP12 each include a block insulating film 58, a charge storage film 56, a tunnel insulating film 54, a channel 52, and a core member 50. The block insulating film 58, the charge storage film 56, the tunnel insulating film 54, the channel 52, and the core member 50 penetrate the insulating layer 36, the conductive layer 38, the plurality of insulating layers 40, the plurality of conductive layers 42, and the conductive layer 44. These memory pillars MP (MP9, MP10, MP11, MP12) have a substantially elliptical outer shape in the plane in parallel with the XY plane. The direction of the minor axis is rotated clockwise by a predetermined angle from the X direction when viewed in the Z direction.

According to the semiconductor storage device according to the third embodiment, the NAND string (memory string) in a memory pillar MP provided below the fourth insulating film 24 may also be used for data storage.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device, comprising:
a semiconductor layer;
a plurality of conductive layers stacked above the semiconductor layer, each conducti00ve layer extending in a plane parallel to a first direction and a second direction intersecting the first direction, each conductive layer being spaced from an adjacent conductive layer in a third direction intersecting the first and second directions; and
a first memory pillar extending in the third direction through the plurality of conductive layers to the semiconductor layer, the first memory pillar including:
a first insulating film on an outer peripheral surface of the first memory pillar and having an elliptical shape in a plane parallel to the first and second directions,
a first channel layer on an interior surface of the first insulating film and extending the length of the first memory pillar in the third direction,
a second channel layer on the interior surface of the first insulating film and extending the length of the first memory pillar, and
an insulating core between the first channel layer and the second channel layer in a direction parallel to a major axis of the elliptical shape of the first memory pillar, wherein
the insulating core electrically insulates the first channel layer from the second channel layer.

2. The semiconductor storage device according to claim 1, wherein, in the plane parallel to the first and second directions, the first channel layer is thickest along the major axis and thins continuously towards a minor axis of the elliptical shape.

3. The semiconductor storage device according to claim 2, wherein, in the plane parallel to the first and second directions, the second channel layer is thickest along the major axis and thins continuously towards the minor axis.

4. The semiconductor storage device according to claim 3, wherein the first channel layer and the second channel layer are symmetric with respect to one another about the minor axis.

5. The semiconductor storage device according to claim 3, wherein the first channel layer and the second channel layer are each crescent shaped in the plane parallel to the first and second directions.

6. The semiconductor storage device according to claim 1, further comprising:
a first contact on an upper end of the first memory pillar in the third direction and electrically connected to the first channel layer; and
a second contact on the upper end of the first memory pillar and electrically connected to the second channel layer, wherein
the first and second contacts are electrically isolated from one another.

7. The semiconductor storage device according to claim 6, further comprising:
a first bit line above the first memory pillar in the first direction and extending in the first direction; and
a second bit line above the first memory pillar in the first direction and extending in the first direction, the second bit line being spaced from the first bit line in the second direction, wherein
the first bit line is electrically connected to the first channel layer via the first contact, and
the second bit line is electrically connected to the second channel layer via the second contact.

8. The semiconductor storage device according to claim 7, wherein the major axis is not parallel to the first direction.

9. The semiconductor storage device according to claim 1, insulating core extends in the minor axis direction through the first insulating film.

10. The semiconductor storage device according to claim 1, wherein the first insulating film includes:
a block insulating film at the outer periphery of the first memory pillar;
a charge storage film on an interior of the block insulating film; and
a tunnel insulating film on an interior of the charge storage film.

11. A semiconductor storage device, comprising:
a semiconductor layer;
a plurality of conductive layers stacked above the semiconductor layer, each conductive layer extending in a plane parallel to a first direction and a second direction intersecting the first direction, each conductive layer being spaced from an adjacent conductive layer in a third direction intersecting the first and second directions;
a plurality of first memory pillars extending in the third direction through the plurality of conductive layers to the semiconductor layer, the first memory pillars spaced from one another in the second direction and having an elliptical shape in a plane parallel to the first and second direction; and
a plurality of second memory pillars extending in the third direction through the plurality of conductive layers to the semiconductor layer, the second memory pillars spaced from one another in the second direction and having an elliptical shape in a plane parallel to the first and second direction, wherein
each first memory pillar and second memory pillar includes:
a first insulating film on an outer peripheral surface,
a first channel layer on an interior surface of the first insulating film and extending the length of the respective first or second memory pillar in the third direction,
a second channel layer on the interior surface of the first insulating film and extending the length of the respective first or second memory pillar, and
an insulating core between the first channel layer and the second channel layer in a direction parallel to a major axis of the elliptical shape of the respective first or second memory pillar, and electrically insulating the first channel layer from the second channel layer,
the first memory pillars each have a minor axis rotated from the first direction by a first predetermined angle from the first direction, and
the second memory pillars each have a minor axis rotated from the first direction by a second predetermined angle from the first direction.

12. The semiconductor storage device according to claim 11, wherein the second predetermined angle and the first predetermined angle are different angles from one another.

13. The semiconductor storage device according to claim 11, wherein the plurality of first memory pillars are spaced from the plurality of second memory pillars in the first direction.

14. The semiconductor storage device according to claim 13, wherein the first memory pillars are at positions along the second direction offset from positions of the second memory pillars along the second direction.

15. The semiconductor storage device according to claim 14, further comprising:
first contacts on an upper end of each of the first memory pillars in the third direction and electrically connected to the first channel layer; and
second contacts on the upper end of each of the first memory pillars and electrically connected to the second channel layer, wherein
the first and second contacts on the first memory pillars are electrically isolated from one another.

16. The semiconductor storage device according to claim 11, further comprising:
a plurality of third memory pillars extending in the third direction through the plurality of conductive layers to the semiconductor layer, the third memory pillars spaced from one another in the second direction and having an elliptical shape in a plane parallel to the first and second direction, wherein
the plurality of first memory pillars are spaced from the plurality of second memory pillars in the first direction,
the plurality of third memory pillars are spaced from the plurality of second memory pillars in the first direction,
the first memory pillars are at positions along the second direction offset from positions of the second memory pillars along the second direction, and
the third memory pillars are at positions along the second direction aligned with the positions of the first memory pillars.

17. The semiconductor storage device according to claim 16, further comprising:
three bit lines spaced from each other in the second direction, the three bit lines being above a first memory pillar in the plurality of first memory pillars and a third memory pillar in the plurality of third memory pillars, wherein
two of the three bit lines are respectively connected to the first and second channel layers of the first memory pillar, and
one of the three bit lines is connected to a channel layer of the third memory pillar.

18. The semiconductor storage device according to claim 11, wherein, in the plane parallel to the first and second directions, the first channel layer of each of the first and second memory pillars is thickest along the major axis and thins continuously towards the minor axis.

19. A method for manufacturing a semiconductor storage device, the method comprising:
forming a stacked body in which a plurality of sacrificial layers and conductive layers are stacked on a semiconductor layer;
forming a hole penetrating the stacked body, the hole having an elliptical shape in a plane parallel to the semiconductor layer;
forming an insulating film on a sidewall of in the hole;
forming a semiconductor film in the hole on the insulating film, the semiconductor film having a tube shape; and
wet etching the semiconductor film from via the tube shape from the inside toward the outside and dividing the semiconductor film into two portions.

20. The method according to claim 19, further comprising:
filling the hole with an insulating core material after the wet etching;
forming a first contact above the hole, the first contact being electrically connected to a first portion of the divided semiconductor film; and
forming a second contact above the hole insulated from the first contact, the second contact being electrically connected to a second portion of the dived semiconductor film but not the first portion.
